(19) United States
(12) Patent Application Publication
(10) Pub. No.: US 2020/0022290 A1
(43) Pub. Date: Jan. 16, 2020

(54) Shields

(71) Applicant: Laird Technologies (Shenzhen) Ltd., Shenzhen (CN)

(72) Inventors: Yi-Shen LIN, New Taipei City (TW); Ming Yueh LIU, Taipei (TW)

(21) Appl. No.: 16/400,268

(22) Filed: May 1, 2019

(30) Foreign Application Priority Data
Jul. 16, 2018 (CN) 201810777548.5
Jul. 16, 2018 (CN) 201821136766.2

(51) Int. Cl. H05K 9/00; H05K 1/18; H05K 7/14

(52) U.S. Cl. CPC H05K 9/0032; H05K 1/181; H05K 2201/10371; H05K 9/0015; H05K 7/1427

(57) ABSTRACT

According to various aspects, exemplary embodiments are disclosed of shields (e.g., board level shields, etc.). In an exemplary embodiment, a shield generally includes one or more sidewalls. An upper portion of the one or more sidewalls define an opening having a perimeter. A lower portion of the one or more sidewalls is configured for installation to a substrate generally about one or more components on the substrate. An electrically-conductive material is disposed along the upper portion of the one or more sidewalls and around the perimeter of the opening. The electrically-conductive material is configured to establish an electrically-conductive pathway between the one or more sidewalls and a device housing when a portion of the device housing is positioned over the opening.

### CROSS-REFERENCE TO RELATED APPLICATIONS

This application claims the benefit and priority of Chinese Invention Patent Application No. 201810777548.5 filed Jul. 16, 2018 and Chinese Utility Model Application 201821136766.2 filed Jul. 16, 2018, which granted on Jan. 11, 2019 as Chinese Utility Model No. ZL 201821136766.2. The entire disclosures of the above applications are incorporated herein by reference.

### FIELD

The present disclosure generally relates to shields, such as board levels shields for providing electromagnetic interference (EMI) shielding.

### BACKGROUND

This section provides background information related to the present disclosure which is not necessarily prior art.

A common problem in the operation of electronic devices is the generation of electromagnetic radiation within the electronic circuitry of the equipment. Such radiation may result in electromagnetic interference (EMI) or radio frequency interference (RFI), which can interfere with the operation of other electronic devices within a certain proximity. Without adequate shielding, EMI/RFI interference may cause degradation or complete loss of important signals, thereby rendering the electronic equipment inefficient or inoperable.

A common solution to ameliorate the effects of EMI/RFI is through the use of shields capable of absorbing and/or reflecting and/or redirecting EMI energy. These shields are typically employed to localize EMI/RFI within its source, and to insulate other devices proximal to the EMI/RFI source. For example, board level shields are widely used to protect sensitive electronic devices against inter and intra system electromagnetic interferences and reduce unwanted electromagnetic radiations from a noisy integrated circuit (IC).

FIG. 1 illustrates an electronic device 11 including a conventional two-piece board level shield (BLS) including a fence 15 and a removable cover 19. The BLS fence 15 defines an opening along a top of the BLS fence 15. The BLS cover 19 is removably attached to the fence 15 to cover the opening defined by the BLS fence 15. The fence 15 is installed to a printed circuit board 23 of the electronic device 11. The BLS fence 15 and cover 19 are operable for providing electromagnetic interference (EMI) shielding for the component 27 on the PCB 23 that is within the interior cooperatively defined by the BLS fence 15 and cover 19. Also shown in FIG. 1, the electronic device 11 further includes a housing, case, or outside box 31 in which are positioned the BLS fence 15, the BLS cover 19, the PCB 23, and PCB component 27.

The BLS fence 15 may be installed to the PCB 23 via a solder reflow process. In order to allow for inspection or other access to the component 27 on the PCB 23, however, the BLS cover 19 is attached to the fence 15 after solder reflow. Accordingly, the conventional two-piece board level shield (BLS) shown in FIG. 1 requires electrically-conductive material for the BLS cover 19, and an additional assembly step of attaching the BLS cover 19 to the BLS fence 15, which BLS cover 19 will also block heat to dissipate from the PCB component 27.

The term “EMI” as used herein should be considered to generally include and refer to EMI emissions and RFI emissions, and the term “electromagnetic” should be considered to generally include and refer to electromagnetic and radio frequency from external sources and internal sources. Accordingly, the term shielding (as used herein) broadly includes and refers to mitigating (or limiting) EMI and/or RFI, such as by absorbing, reflecting, blocking, and/or redirecting the energy or some combination thereof so that it no longer interferes, for example, for government compliance and/or for internal functionality of the electronic component system.

### SUMMARY

This section provides a general summary of the disclosure, and is not a comprehensive disclosure of its full scope or all of its features.

According to various aspects, exemplary embodiments are disclosed of shields (e.g., board level shields, etc.). In an exemplary embodiment, a shield generally includes one or more sidewalls. An upper portion of the one or more sidewalls define an opening having a perimeter. A lower portion of the one or more sidewalls is configured for installation to a substrate generally about one or more components on the substrate. An electrically-conductive material is disposed along the upper portion of the one or more sidewalls and around the perimeter of the opening. The electrically-conductive material is configured to establish an electrically-conductive pathway between the one or more sidewalls and a device housing when a portion of the device housing is positioned over the opening. The shield may be operable for providing electromagnetic interference (EMI) shielding for the one or more components on the substrate that are within an interior cooperatively defined by the one or more sidewalls, the electrically-conductive material, and the portion of the device housing.

The one or more sidewalls and the electrically-conductive material may be able to withstand solder reflow temperatures up to at least about 265 degrees Celsius.

The lower portion of the one or more sidewalls may be installed, via a solder reflow process, to the substrate generally about the one or more components on the substrate. The substrate including the one or more sidewalls installed thereto and the electrically-conductive material may be positioned within the device housing such that the portion of the device housing is positioned over the opening defined by the upper portion of the one or more sidewalls, and such that the electrically-conductive material provides electrical contact between the device housing and the one or more sidewalls.

The electrically-conductive material may comprise an electrically-conductive gasket. The electrically-conductive gasket may comprise an electrically-conductive elastomer, a fabric-over-foam gasket, or a fingerstock gasket. The electrically-conductive gasket may comprise a polymeric elastomer material with electrically conductive particles dispersed therein. The electrically-conductive gasket may comprise a resilient core member, an electrically-conductive layer, and adhesive bonding the electrically-conductive layer to the resilient core member. The electrically-conductive gasket may comprise a base and one or more resiliently flexible spring fingers extend upwardly relative to the base.

The upper portion of the one or more sidewalls may include an inwardly extending rim that defines the opening. The electrically-conductive gasket may be disposed along an upper surface of the inwardly extending rim.

The electrically-conductive gasket may be adhesively attached via an electrically-conductive adhesive to an upper surface of the inwardly extending rim. The electrically-conductive adhesive and the electrically-conductive gasket may be able to withstand solder reflow temperatures up to at least about 265 degrees Celsius.

The electrically-conductive gasket may be a single continuous gasket that extends entirely around the perimeter of the opening defined by the upper portion of the one or more sidewalls.

The shield may further include a thermal interface material configured to establish a thermally-conductive heat path from the one or more components to the device housing when the portion of the device housing is positioned over the opening.

The one or more sidewalls may have a height less than a height of the one or more components. A combined height of the one or more sidewalls and the electrically-conductive material may be greater than a height of the one or more components.

The shield may include the portion of the device housing that is operable as a lid for covering the opening, such that the shield does not include a separate lid that is attachable to the one or more sidewalls for covering the opening.

A device may include the shield and a printed circuit board having one or more components thereon. The lower portion of the one or more sidewalls may be installed to the printed circuit board generally about the one or more components on the printed circuit board. The one or more sidewalls, the electrically-conductive material, and the printed circuit board may be positioned within the device housing such that the portion of the device housing is positioned over the opening defined by the upper portion of the one or more sidewalls, and such that the electrically-conductive material provides electrical contact between the device housing and the one or more sidewalls. The shield may be operable for providing electromagnetic interference (EMI) shielding for the one or more components on the printed circuit board that are within an interior cooperatively defined by the one or more sidewalls, the electrically-conductive material, and the portion of the device housing.

A thermal interface material may be disposed between the device housing and the one or more components of the printed circuit board. The thermal interface material may establish a thermally-conductive pathway from the one or more components to the device housing. A lower portion of the thermal interface material may be in direct physical contact with an upper surface of the one or more components. An upper portion of the thermal interface material may be in direct physical contact with an inner surface of the portion of the device housing.

The one or more sidewalls may have a height less than a height of the one or more components on the printed circuit board, such that the one or more components extend through and above the opening defined by the upper portion of the one or more sidewalls.

A combined height of the one or more sidewalls and the electrically-conductive material may be greater than a height of the one or more components on the printed circuit board, such that the electrically-conductive material is compressed between the one or more sidewalls and the device housing.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 illustrates a device including a conventional two-piece board level shield (BLS) including a fence and a removable cover.

FIG. 2 illustrates a device including a board level shield according to an exemplary embodiment.

### DETAILED DESCRIPTION

Example embodiments will now be described more fully with reference to the accompanying drawings.

Disclosed herein are exemplary embodiments of board level shields (broadly, shields or shielding assemblies, etc.) in which a portion of a device housing, case, or outside box is positioned over and covers an opening (e.g., open top, etc.) defined by a BLS fence or frame (broadly, one or more sidewalls). Accordingly, a separate BLS cover or lid does not have to be removably attached to the one or more sidewalls for covering the opening defined by the fence or frame.

In an exemplary embodiment, a shielding assembly or apparatus (e.g., board level shield, etc.) generally includes one or more sidewalls including an upper portion (e.g., inwardly extending rim, flange, lip, or shoulder, etc.) and a lower portion (e.g., mounting feet, etc.). The upper portion defines an opening having a perimeter. The lower portion is configured for installation (e.g., solderable, etc.) to a substrate (e.g., PCB, etc.) generally about one or more components on the substrate.

An electrically-conductive material (e.g., electrically-conductive gasket, electrically-conductive elastomer, fabric-over-foam (FOF) EMI gasket, fingerstock EMI gasket, etc.) is disposed along (e.g., adhesively attached via an electrically-conductive adhesive, etc.) the upper portion of the one or more sidewalls. The electrically-conductive material is disposed (e.g., entirely, at least partially, etc.) around the perimeter of the opening.

The electrically-conductive material is configured to establish an electrically-conductive pathway between the one or more sidewalls and an electrically-conductive structure (e.g., device housing, case, outside box, other electrically-conductive enclosure, etc.) when a portion of the electrically-conductive structure is positioned over and covers the opening defined by the upper portion of the one or more sidewalls.

The shielding assembly is operable for providing electromagnetic interference (EMI) shielding for the one or more components on the substrate that are within an interior cooperatively defined by the one or more sidewalls, the electrically-conductive material, and the portion of the electrically-conductive structure.

In exemplary embodiments, the one or more sidewalls and the electrically-conductive material are preferably capable of withstanding solder reflow conditions and the temperatures (and temperature changes) associated therewith (e.g., temperatures up to at least about 265 or 280 degrees Celsius, etc.). In exemplary embodiments in which the electrically-conductive material is attached to the one or more sidewalls via an electrically-conductive adhesive, the adhesive is also preferably capable of withstanding solder reflow conditions and the temperatures (and temperature changes) associated therewith. As such, the shielding assembly can maintain its operational integrity (e.g., in terms of structure (e.g., without failure of the adhesive bond, etc.), performance, etc.) following the reflow soldering operation.

By eliminating the need for a separate BLS cover, exemplary embodiments disclosed herein may thus eliminate the costs to manufacture the BLS cover and the steps of assembling the cover to the BLS fence. Without a BLS cover on the BLS fence that would otherwise block access to components on the PCB, the PCB components may be easily inspected through the opening or open top of the BLS fence after the BLS fence has been installed to the PCB. In addition, the elimination of the BLS cover may also allow for reductions in the overall height and weight of the BLS. A thermal interface material may also be disposed directly between a PCB component and the device housing.

FIG. 2 illustrates a device 100 (e.g., smartphone, tablet, portable device, other electronic device, etc.) including a board level shield (BLS) (broadly, a shield, shielding assembly or apparatus) according to an exemplary embodiment. As shown, an electrically-conductive gasket 104 (broadly, an electrically-conductive material) is on top of a BLS fence or frame 108.

The BLS fence 108 includes sidewalls 112 configured (e.g., sized, shaped, arranged, etc.) to be disposed generally around one or more components 132 on the PCB 128. An upper portion 116 of the sidewalls 112 define an opening 120 (e.g., open top, etc.) having a perimeter. The electrically-conductive gasket 104 is disposed (e.g., entirely, at least partially, etc.) around the perimeter of the opening 120. A lower portion 124 of the sidewalls 112 are configured for installation to a printed circuit board (PCB) 128 (broadly, a substrate or support surface).

By way of example, the lower portion 124 may include mounting feet configured to provide structure for soldering the sidewalls 112 to the PCB 128. In such embodiments, the empty space or gap between adjacent mounting feet may allow solder to flow around the mounting feet for securing the sidewalls 112 to the PCB 128. The mounting feet may be soldered to solder pads and/or vias (broadly, electrically-conductive portions) on the PCB 128 such that the solder provides a direct electrical connection from the mounting feet along the bottom of the sidewalls 112 to the solder pads and/or vias, which may be directly connected to the PCB ground.

In this exemplary embodiment, the upper portion 116 of the sidewalls 112 includes an inwardly extending rim, flange, lip, or shoulder defining an upper surface along which the gasket 104 is disposed. But other exemplary embodiments may include a BLS fence or frame with a flangeless construction without an inwardly extending lip, rim, flange, or shoulder.

An electrically-conductive adhesive may be used to adhesively attach the gasket 104 on top of the inwardly extending rim, flange, lip or shoulder of the sidewall upper portion 116. The electrically-conductive adhesive may help provide good EMI shielding effectiveness and/or may be capable of withstanding solder reflow conditions and temperatures (e.g., temperatures up to at least about 265 or 280 degrees Celsius, etc.). The adhesive may be a silicone-based adhesive (e.g., a silicone pressure sensitive adhesive, etc.). In other embodiments, other adhesives may be used, such as solvent based polyester adhesives, epoxy-based adhesives, hot melt adhesives, combinations thereof, etc. The adhesive may also have no more than a maximum of 900 parts per million chlorine, no more than a maximum of 900 parts per million bromine, and no more than a maximum of 1,500 parts per million total halogens such that the adhesive is halogen free.

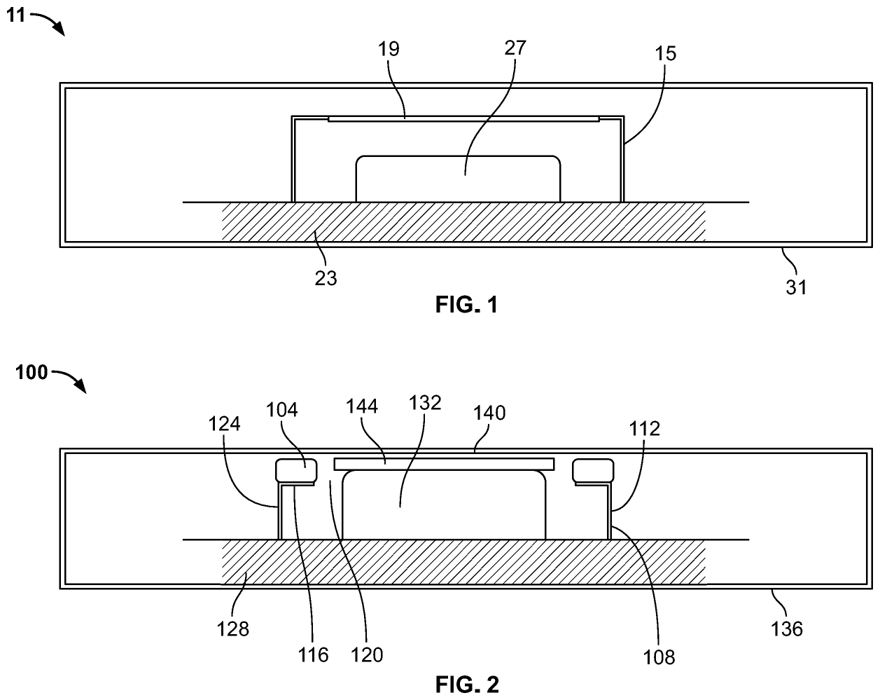

As shown in FIG. 2, the electrically-conductive gasket 104 is between (e.g., directly between, compressed between, abutting against, etc.) the upper portion 116 of the sidewalls 112 and a device housing 136 (e.g., device exterior case, outside box, electrically-conductive enclosure, etc.). A portion 140 of the device housing 136 is disposed over and covers the opening 120 defined by the sidewalls 112 of the BLS fence 108. Accordingly, the portion 140 of the device housing 136 is used to cover the open top 120 of the BLS fence 108 instead of a conventional cover or lid 19 as shown in FIG. 1.

The electrically-conductive gasket 104 establishes an electrically-conductive pathway between the sidewalls 112 and the device housing 136. The portion 140 of the device housing 136, the electrically-conductive gasket 104, and the sidewalls 112 are operable for providing EMI shielding for the component 132 on the PCB 128 that are within the interior cooperatively defined by the sidewalls 112, the electrically-conductive gasket 104, and the portion 140 of the device housing 136.

In this exemplary embodiment, the sidewalls 112, the electrically-conductive gasket 104, and electrically-conductive adhesive used to attach the gasket 104 to the sidewalls 112 are capable of withstanding solder reflow conditions and the temperatures (and temperature changes) associated therewith (e.g., temperatures up to at least about 265 degrees or 280 degrees Celsius, etc.). For example, during the reflow soldering process, the sidewalls 112, the electrically-conductive gasket 104, and electrically-conductive adhesive may be subjected to various temperatures ranging from about 20 degrees Celsius (room temperature) up to about 265 degrees Celsius for extended periods of time (e.g., about 30 seconds, etc.). During this reflow soldering process, the sidewalls 112, the electrically-conductive gasket 104, and electrically-conductive adhesive are able to withstand these varying temperatures without breaking down.

The electrically-conductive gasket 104 may be adhesively attached to the sidewalls 112 via an electrically-conductive adhesive. Thereafter, the sidewalls 112 and gasket 104 adhesively attached thereto may be sent to another location to undergo a solder reflow process for installing the sidewalls 112 to the PCB 128. After the solder reflow process, the PCB component 132 may be easily accessed or inspected through the open top 120 of the BLS fence 108 because there is no BLS cover or lid that would otherwise block access to the PCB component 132. The PCB 128, sidewalls 112, and gasket 104 may then be positioned within the device housing 136 such that the portion 140 of the device housing 136 covers the open top 120 of the BLS fence 108 and such that the gasket 104 establishes an electrically-conductive pathway between the sidewalls 112 and the device housing 136.

A thermal interface material 144 may be disposed between the PCB component 132 (or other heat source) and the device housing 136. In this exemplary embodiment, the thermal interface material 144 is directly between and in physical contact with (e.g., compressed between, etc.) both the PCB component 132 and the device housing 136.

An upper portion of the thermal interface material 144 is in direct physical contact with an inner surface of the portion 140 of the device housing 136.

A lower portion of the thermal interface material 144 is in direct physical contact with an upper surface or top of the PCB component 132. A middle portion of the thermal interface material 144 may be disposed within the opening 120 of the BLS fence 108, such that the thermal interface material 144 may extend above, through, and below the opening 120. Or, for example, the BLS fence 108 may have a height less than a height of the PCB component 132, such that a portion of the PCB component 132 is within the opening 120. In which case, the PCB component 132 may extend above, through, and below the opening 120. In this latter example, the total combined height of the BLS fence 108 and electrically-conductive gasket 104 may be greater than the height of the PCB component 132.

The thermal interface material 144 establishes a thermally-conductive pathway or heat path from the PCB component 132 to the device housing 136. Accordingly, heat may be transferred from the PCB component 132 through the thermal interface material 144 to the device housing 136, and then dissipated from the device housing 136 to the ambient environment. In other exemplary embodiments, one or more heat removal/dissipation structures or components (e.g., a heat spreader, a heat sink, a heat pipe, etc.) may be disposed between the thermal interface material 144 and the device housing 136 and/or between the thermal interface material 144 and the PCB component 132.

In exemplary embodiments, the electrically-conductive gasket 104 may also be thermally-conductive. In such exemplary embodiments, the gasket 104 may establish a thermally-conductive and electrically-conductive pathway between the BLS fence 108 and the device housing 136. Accordingly, heat may be transferred to the BLS fence 108 from within the interior defined by the gasket 104, BLS fence 108, and device housing 136. The heat may then be transferred along the BLS fence 108 through the gasket 104 to the device housing 136, and then dissipated from the device housing 136 to the ambient environment. By way of example, the gasket 104 may comprise a matrix or base material (e.g., silicone elastomer, etc.) including both thermally-conductive filler and electrically-conductive filler and/or a filler that is both thermally-conductive filler and electrically-conductive.

By way of example, the electrically-conductive gasket 104 may comprise a single continuous gasket that extends (e.g., extruded, formed-in-place, manually or automatically placed, etc.) around the entire perimeter of the opening 120, such that there are no gaps large enough through which EMI may escape. Or, for example, the electrically-conductive gasket 104 may comprise two or more gasket portions in contact with each other such that the two or more portions define or provide electrically-conductive material around the entire perimeter of the opening 120, such that there are no gaps large enough through which EMI may escape. As yet another example, the electrically-conductive gasket 104 may comprise two or more gasket portions spaced apart from each other with gaps therebetween which gaps are eliminated when the gasket portions are compressed between the sidewalls 112 and the device housing 136.

A wide range of electrically-conductive gaskets may be used for the electrically-conductive gasket 104, such as electrically-conductive elastomers (EcE), fabric-over-foam (FOF) EMI gaskets, fingerstock EMI gaskets, other gaskets, etc. The electrically-conductive gasket 104 may be provided along the upper surface of the sidewalls 112 by different processes (e.g., extrusion, etc.) depending on the particular type of gasket.

The electrically-conductive gasket 104 may be capable of withstanding solder reflow conditions and temperatures (e.g., temperatures up to at least about 265 or 280 degrees Celsius, etc.). The electrically-conductive gasket 104 may achieve a flame rating of V-0 under UL-94, may be RoHS compliant, and may be halogen free as defined by the IEC 61249-2-21 standard (have no more than a maximum of 900 parts per million chlorine, no more than a maximum of 900 parts per million bromine, and no more than a maximum of 1,500 parts per million total halogens).

In an exemplary embodiment, the electrically-conductive gasket 104 comprises electrically-conductive elastomer that is formed of a polymeric elastomer material with electrically conductive particles dispersed therein. The electrically-conductive particles may be formed of a variety of different materials, such as nickel, copper, silver, gold, aluminum, a nickel/graphite combination, a silver/copper combination, a silver/aluminum combination, a silver/nickel combination, other metallic materials, combinations thereof, etc. The size, shape, density, etc. of the electrically-conductive particles may be based on, for example, desired thermal characteristics, electrically conductivity characteristics, electromagnetic shielding characteristics, compressibility, etc.

In another exemplary embodiment, the electrically-conductive gasket 104 comprises a fabric-over-foam (FOF) type of EMI gasket. In this example, the electrically-conductive gasket 104 includes a resilient core member, an electrically-conductive layer, and adhesive bonding the electrically-conductive layer to the resilient core member. The electrically-conductive layer may comprise a metallized film, such as a metallized polyimide film, etc.

The resilient core member may comprise a foam material (e.g., a silicone foam material, a polymeric elastomer material, a cellular polymeric foam such as an open celled foam, a closed cell foam, a neoprene foam, a urethane foam (e.g., a polyester foam, a polyether foam, a combination thereof, etc.), a polyurethane foam, etc.), a silicone rubber material, etc. The adhesive may be a silicone-based adhesive (e.g., a silicone pressure sensitive adhesive, etc.). The adhesive may be loaded with an effective amount of flame retardant (e.g., halogen-free flame retardant free of halogens, such as bromines and chlorines, etc.) to enable the gasket 104 to achieve a UL-94 flame rating of V-0, while at the same time having good bond strength and retaining properties suitable (e.g., bulk resistivity, etc.) for the desired contact applications. In other embodiments, other adhesives may be used such as solvent based polyester adhesives, epoxy-based adhesives, hot melt adhesives, combinations thereof, etc.

In a further exemplary embodiment, the electrically-conductive gasket 104 comprises a fingerstock EMI gasket. In this example, the electrically-conductive gasket 104 may include a base and resiliently flexible spring fingers. The base may be configured to be coupled along the upper surface of the sidewalls 112 of the BLS fence 108. The resiliently flexible spring fingers may extend upwardly from the base and sidewalls 112 towards the device housing 136. The spring fingers may be configured to flex or deform downwardly from their original or initial position when compressed between the BLS fence 108 and device housing 136. The spring fingers may be generally resilient in nature, which urges the compressed spring fingers to return to their original or initial positioning. This, in turn, helps create good electrical contact between the electrically-conductive gasket 104 and the BLS fence 108 and device housing 136.

The BLS fence 108 may be formed from a single piece of electrically-conductive material so that the side walls 112 have an integral, monolithic construction. A wide range of electrically-conductive materials may be used for the BLS fence 108, such as phosphor bronze, copper-clad steel, brass, monel, nickel silver alloys, aluminum, aluminum alloys, steels, stainless steels, carbon steel, cold rolled steel, sheet metal, brass, copper, copper nickel alloys, beryllium copper alloys, other copper based alloys, alloys of magnesium, among others. In an exemplary embodiment, a flat profile pattern for the BLS fence 108 may be stamped into a piece of material. The sidewalls 112 may then be formed, bent, drawn, shaped, folded, etc. Even though the BLS fence 108 may be integrally formed (e.g., stamping and bending/folding/drawing, etc.) from a single piece of material substantially simultaneously in this example, such is not required for all embodiments.

The device housing 136 may be made out of a wide range of materials. By way of example, the device housing 136 may be made of aluminum, although other metals, alloys, and non-metals may also be used. In addition, aspects of the present disclosure may be used with various devices, such as smartphones, tablets, laptops, other portable devices, other electronic devices, etc. Accordingly, the present disclosure should not be limited to use with any one particular type of device, printed circuit board, PCB component, etc.

A wide range of thermal interface materials may be used for the thermal interface material 144, such as thermal gap fillers, thermal phase change materials, thermally-conductive EMI absorbers or hybrid thermal/EMI absorbers, thermal greases, thermal pastes, thermal putties, dispensable thermal interface materials, thermal pads, etc. In addition to, or instead of, a thermal interface material, exemplary embodiments may include one or more EMI absorbers (e.g., ultrathin nearfield noise suppression absorber, etc.).

The thermal interface material 144 may comprise an elastomer and/or ceramic particles, metal particles, ferrite EMI/RFI absorbing particles, metal or fiberglass meshes in a base of rubber, gel, or wax, etc. The thermal interface material 144 may include compliant or conformable silicone pads, non-silicone based materials (e.g., non-silicone based gap filler materials, thermoplastic and/or thermoset polymeric, elastomeric materials, etc.), silk screened materials, polyurethane foams or gels, thermally-conductive additives, etc. The thermal interface material 144 may be configured to have sufficient conformability, compliability, and/or softness (e.g., without having to undergo a phase change or reflow, etc.) to adjust for tolerance or gaps by deflecting at low temperatures (e.g., room temperature of 20° C. to 25° C., etc.) and/or to allow the thermal interface material 144 to closely conform (e.g., in a relatively close fitting and encapsulating manner, etc.) to a mating surface when placed in contact with (e.g., compressed against, etc.) the mating surface, including a non-flat, curved, or uneven mating surface.

The thermal interface material 144 may include a soft thermal interface material formed from elastomer and at least one thermally-conductive metal, boron nitride, and/or ceramic filler, such that the soft thermal interface material is conformable even without undergoing a phase change or reflow. The thermal interface material 144 may include ceramic filled silicone elastomer, boron nitride filled silicone elastomer, or a thermal phase change material that includes a generally non-reinforced film.

The thermal interface material 144 may have a relatively high thermal conductivity (e.g., 1 Watt per meter-Kelvin (W/mK), 2 W/mK, 3 W/mK, 4 W/mK, 5 W/mK, 6 W/mK, etc.) depending on the particular materials used to make the thermal interface material and filler loading percentage. These thermal conductivities are only examples as other embodiments may include a thermal management and/or EMI mitigation material with a thermal conductivity higher than 6 W/mK, less than 1 W/mK, or other values between 1 and 6 W/mk. Accordingly, aspects of the present disclosure should not be limited to use with any particular thermal interface material as exemplary embodiments may include a wide range of thermal interface materials.

Also disclosed herein are exemplary methods relating to electromagnetic interference (EMI) shielding for one or more components on a substrate. In exemplary embodiments, a method includes providing an electrically-conductive material along an upper portion of one or more sidewalls that defines an opening having a perimeter, such that the electrically-conductive material is disposed around the perimeter of the opening. The one or more sidewalls include a lower portion configured for installation to the substrate generally about the one or more components on the substrate. The electrically-conductive material is configured to establish an electrically-conductive pathway between the one or more sidewalls and a device housing when a portion of the device housing is positioned over the opening. The one or more sidewalls and the electrically-conductive material are able to withstand solder reflow temperatures.

In exemplary embodiments, the electrically-conductive material comprises an electrically-conductive gasket. The step of providing the electrically-conductive material along the upper portion of the one or more sidewalls includes using an electrically-conductive adhesive to adhesively attach the electrically-conductive gasket to the upper portion of the one or more sidewalls. The electrically-conductive adhesive is able to withstand solder reflow temperatures.

In exemplary embodiments, the method further includes after adhesively attaching the electrically-conductive gasket, installing the lower portion of the one or more sidewalls, via a solder reflow process, to the substrate generally about the one or more components on the substrate. The method also includes positioning the substrate including the one or more sidewalls installed thereto and the electrically-conductive material adhesively attached to the one or more sidewalls within the device housing such that the portion of the device housing is positioned over the opening defined by the upper portion of the one or more sidewalls, and such that the electrically-conductive material provides electrical contact between the device housing and the one or more sidewalls.

In exemplary embodiments, the method further comprises after installing the lower portion of the one or more sidewalls, via the solder reflow process, to the substrate, inspecting and/or accessing the one or more components on the substrate through the opening before the portion of the device housing is positioned over the opening.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms, and that neither should be construed to limit the scope of the disclosure. In some example embodiments, well-known processes, well-known device structures, and well-known technologies are not described in detail. In addition, advantages and improvements that may be achieved with one or more exemplary embodiments of the present disclosure are provided for purpose of illustration only and do not limit the scope of the present disclosure, as exemplary embodiments disclosed herein may provide all or none of the above mentioned advantages and improvements and still fall within the scope of the present disclosure.

Specific dimensions, specific materials, and/or specific shapes disclosed herein are example in nature and do not limit the scope of the present disclosure. The disclosure herein of particular values and particular ranges of values for given parameters are not exclusive of other values and ranges of values that may be useful in one or more of the examples disclosed herein. Moreover, it is envisioned that any two particular values for a specific parameter stated herein may define the endpoints of a range of values that may be suitable for the given parameter (i.e., the disclosure of a first value and a second value for a given parameter can be interpreted as disclosing that any value between the first and second values could also be employed for the given parameter). For example, if Parameter X is exemplified herein to have value A and also exemplified to have value Z, it is envisioned that parameter X may have a range of values from about A to about Z. Similarly, it is envisioned that disclosure of two or more ranges of values for a parameter (whether such ranges are nested, overlapping or distinct) subsume all possible combination of ranges for the value that might be claimed using endpoints of the disclosed ranges. For example, if parameter X is exemplified herein to have values in the range of 1-10, or 2-9, or 3-8, it is also envisioned that Parameter X may have other ranges of values including 1-9, 1-8, 1-3, 1-2, 2-10, 2-8, 2-3, 3-10, and 3-9.

The terminology used herein is for the purpose of describing particular example embodiments only and is not intended to be limiting. For example, when permissive phrases, such as “may comprise”, “may include”, and the like, are used herein, at least one shield comprises or includes the feature(s) in at least one exemplary embodiment. As used herein, the singular forms “a”, “an” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on”, “engaged to”, “connected to” or “coupled to” another element or layer, it may be directly on, engaged, connected or coupled to the other element or layer, or intervening elements or layers may be present. In contrast, when an element is referred to as being “directly on,” “directly engaged to”, “directly connected to” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

The term “about” when applied to values indicates that the calculation or the measurement allows some slight imprecision in the value (with some approach to exactness in the value; approximately or reasonably close to the value; nearly). If, for some reason, the imprecision provided by “about” is not otherwise understood in the art with this ordinary meaning, then “about” as used herein indicates at least variations that may arise from ordinary methods of measuring or using such parameters. For example, the terms “generally”, “about”, and “substantially” may be used herein to mean within manufacturing tolerances.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section could be termed a second element, component, region, layer or section without departing from the teachings of the example embodiments.

Spatially relative terms, such as “inner,” “outer,” “beneath”, “below”, “lower”, “above”, “upper” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The foregoing description of the embodiments has been provided for purposes of illustration and description. It is not intended to be exhaustive or to limit the disclosure. Individual elements, intended or stated uses, or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A board level shield suitable for providing electromagnetic interference (EMI) shielding for one or more components on a substrate, the board level shield comprising:
a fence including an upper portion defining an opening having a perimeter, and a lower portion configured for installation to the substrate generally about the one or more components on the substrate; and
an electrically-conductive gasket disposed along the upper portion of the fence and around the perimeter of the opening, the electrically-conductive gasket configured to establish an electrically-conductive pathway between the fence and a device housing when a portion of the device housing is positioned over the opening.

2. The board level shield of claim 1, wherein the fence and the electrically-conductive gasket are able to withstand solder reflow temperatures up to at least about 265 degrees Celsius.

3. The board level shield of claim 1, wherein:
the lower portion of the fence is installed, via a solder reflow process, to the substrate generally about the one or more components on the substrate;
the substrate including the fence installed thereto and the electrically-conductive gasket are positioned within the device housing such that:
the portion of the device housing is positioned over the opening defined by the upper portion of the fence; and
the electrically-conductive gasket provides electrical contact between the device housing and the fence.

4. The board level shield of claim 1, wherein the electrically-conductive gasket comprises an electrically-conductive elastomer, a fabric-over-foam gasket, or a fingerstock gasket.

5. The board level shield of claim 1, wherein the electrically-conductive gasket comprises:
a polymeric elastomer material with electrically conductive particles dispersed therein; or
a resilient core member, an electrically-conductive layer, and adhesive bonding the electrically-conductive layer to the resilient core member; or
a base and one or more resiliently flexible spring fingers extend upwardly relative to the base.

6. The board level shield of claim 1, wherein:
the upper portion of the fence includes an inwardly extending rim that defines the opening;
the electrically-conductive gasket is adhesively attached via an electrically-conductive adhesive to an upper surface of the inwardly extending rim; and
the electrically-conductive adhesive and the electrically-conductive gasket are able to withstand solder reflow temperatures up to at least about 265 degrees Celsius.

7. The board level shield of claim 1, wherein the electrically-conductive gasket is a single continuous gasket that extends entirely around the perimeter of the opening defined by the upper portion of the fence.

8. The board level shield of claim 1, further comprising a thermal interface material configured to establish a thermally-conductive heat path from the one or more components to the device housing when the portion of the device housing is positioned over the opening.

9. The board level shield of claim 1, wherein the portion of the device housing is positionable over the opening such that the board level shield does not include a lid attachable to the fence for covering the opening.

10. The board level shield of claim 1, wherein the board level shield includes the portion of the device housing that is operable as a lid for covering the opening, such that the board level shield does not include a separate lid that is attachable to the fence for covering the opening.

11. A device comprising the board level shield of claim 1 and a printed circuit board having one or more components thereon, wherein:
the lower portion of the fence is installed to the printed circuit board generally about the one or more components on the printed circuit board; and
the fence, the electrically-conductive gasket, and the printed circuit board are positioned within the device housing such that the portion of the device housing is positioned over the opening defined by the upper portion of the fence, and such that the electrically-conductive gasket provides electrical contact between the device housing and the fence;
whereby the board level shield is operable for providing electromagnetic interference (EMI) shielding for the one or more components on the printed circuit board that are within an interior cooperatively defined by the fence, the electrically-conductive gasket, and the portion of the device housing.

12. The device of claim 11, further comprising a thermal interface material between the device housing and the one or more components of the printed circuit board, wherein the thermal interface material establishes a thermally-conductive pathway from the one or more components to the device housing.

13. The device of claim 11, wherein:
the fence have a height less than a height of the one or more components on the printed circuit board, such that the one or more components extend through and above the opening defined by the upper portion of the fence; and/or
a combined height of the fence and the electrically-conductive gasket is greater than a height of the one or more components on the printed circuit board, such that the electrically-conductive gasket is compressed between the fence and the device housing.

14. A shield comprising:
one or more sidewalls including an upper portion defining an opening having a perimeter, and a lower portion configured for installation to a substrate generally about one or more components on the substrate; and
an electrically-conductive material disposed along the upper portion of the one or more sidewalls and around the perimeter of the opening, the electrically-conductive material configured to establish an electrically-conductive pathway between the one or more sidewalls and a device housing when a portion of the device housing is positioned over the opening, whereby the shield is operable for providing electromagnetic interference (EMI) shielding for the one or more components on the substrate that are within an interior cooperatively defined by the one or more sidewalls, the electrically-conductive material, and the portion of the device housing.

15. The shield of claim 14, wherein:
the one or more sidewalls and the electrically-conductive material are able to withstand solder reflow temperatures up to at least about 265 degrees Celsius;
the lower portion of the one or more sidewalls is installed, via a solder reflow process, to the substrate generally about the one or more components on the substrate; and
the substrate including the one or more sidewalls installed thereto and the electrically-conductive material are positioned within the device housing such that:
the portion of the device housing is positioned over the opening defined by the upper portion of the one or more sidewalls; and
the electrically-conductive material provides electrical contact between the device housing and the one or more sidewalls.

16. The shield of claim 14, wherein:
the electrically-conductive material comprises an electrically-conductive gasket;
the upper portion of the one or more sidewalls includes an inwardly extending rim that defines the opening; and
the electrically-conductive gasket is adhesively attached via an electrically-conductive adhesive to an upper surface of the inwardly extending rim; and
the electrically-conductive adhesive and the electrically-conductive gasket are able to withstand solder reflow temperatures up to at least about 265 degrees Celsius.

17. The shield of claim 14, further comprising a thermal interface material configured to establish a thermally-conductive heat path from the one or more components to the device housing when the portion of the device housing is positioned over the opening.

18. A device comprising the shield of claim 14 and a printed circuit board having one or more components thereon, wherein:
the lower portion of the one or more sidewalls is installed to the printed circuit board generally about the one or more components on the printed circuit board; and
the one or more sidewalls, the electrically-conductive material, and the printed circuit board are positioned within the device housing such that the portion of the device housing is positioned over the opening defined by the upper portion of the one or more sidewalls, and such that the electrically-conductive material provides electrical contact between the device housing and the one or more sidewalls;
whereby the shield is operable for providing electromagnetic interference (EMI) shielding for the one or more components on the printed circuit board that are within an interior cooperatively defined by the one or more sidewalls, the electrically-conductive material, and the portion of the device housing.

19. The device of claim 18, wherein:
the device further comprises a thermal interface material between the device housing and the one or more components of the printed circuit board, wherein the thermal interface material includes a lower portion in direct physical contact with an upper surface of the one or more components, and an upper portion in direct physical contact with an inner surface of the portion of the device housing, whereby the thermal interface material establishes a thermally-conductive pathway from the one or more components to the device housing; and/or
the one or more sidewalls have a height less than a height of the one or more components on the printed circuit board, such that the one or more components extend through and above the opening defined by the upper portion of the one or more sidewalls, and a combined height of the one or more sidewalls and the electrically-conductive material is greater than a height of the one or more components on the printed circuit board, such that the electrically-conductive material is compressed between the one or more sidewalls and the device housing.

20. A method relating to electromagnetic interference (EMI) shielding for one or more components on a substrate, the method comprising providing an electrically-conductive material along an upper portion of one or more sidewalls that defines an opening having a perimeter, such that the electrically-conductive material is disposed around the perimeter of the opening, wherein:
the one or more sidewalls include a lower portion configured for installation to the substrate generally about the one or more components on the substrate;
the electrically-conductive material is configured to establish an electrically-conductive pathway between the one or more sidewalls and a device housing when a portion of the device housing is positioned over the opening; and
the one or more sidewalls and the electrically-conductive material are able to withstand solder reflow temperatures.
